(19) United States
(12) Patent Application Publication
(10) Pub. No.: US 2009/0267465 A1
(43) Pub. Date: Oct. 29, 2009

(54) MICROCOMPUTER CASE

(75) Inventor: TA-YANG CHENG, Taipei (TW)

Correspondence Address: SCHMEISER, OLSEN & WATTS, 22 CENTURY HILL DRIVE, SUITE 302, LATHAM, NY, 12110, US

(73) Assignee: KING YOUNG TECHNOLOGY CO., LTD., TAIPEI CITY (TW)

(21) Appl. No.: 12/109,527

(22) Filed: Apr. 25, 2008

(51) Int. Cl. A47B 81/00; H05K 5/00

(52) U.S. Cl. 312/223.2

(57) ABSTRACT

A microcomputer case includes a base and a top cover detachably assembled to a top of the base. The base includes a bottom wall and two upright side walls perpendicularly upward extended from two lateral edges of the bottom wall. Each of the two upright side walls is formed along an outer corner of a free edge with an insertion channel. The top cover is provided along two lower lateral edges with two downward extended insertion ribs corresponding to the insertion channels on the base. The insertion ribs of the top cover are slidably fitted in the insertion channels of the base, enabling the microcomputer case to be easily disassembled and reassembled for carrying out the expansion of internal and external hardware thereof.

### FIELD OF THE INVENTION

The present invention relates to a microcomputer case, and more particularly to a microcomputer case that can be easily assembled and disassembled to enable convenient expansion of internal and external hardware thereof.

### BACKGROUND OF THE INVENTION

In the computer case of a personal computer, there are mounted various components, including motherboard, hard disc drive, floppy disc drive, CD-ROM drive, recorder, power supply, heat radiator, etc. The motherboard is electrically connected to other components via flat cables. Various factors, such as the large volume of the heat radiator, the improper arrangement of different components in the computer case, and the large space occupied by the flat cables, result in a huge volume of the computer case.

A microcomputer is developed to improve the large case of the personal computer. However, due to limited usable internal space, some components are omitted from the microcomputer case. As a result, the microcomputer loses certain functions and fails to satisfy some users. However, a user may expand the hardware in the microcomputer case according to personal need. To add an additional hard disc to the microcomputer, for example, it is necessary to disassemble the whole microcomputer case to take out the motherboard before carrying out the expansion of hard disk. Troublesome and complicated procedures are involved in disassembling and reassembling the microcomputer case. Moreover, the stacked hard discs have an overall height larger than an initial height of the microcomputer case, and can no longer be accommodated in the case. Under this circumstance, a user has to buy a higher case for accommodating the expanded motherboard. By doing this, the user has to expand the microcomputer with increased cost. Also, to meet different user requirements, a computer case manufacturer has to manufacture and stock cases of various sizes, which results in higher manufacturing and warehousing costs.

### SUMMARY OF THE INVENTION

It is therefore a primary object of the present invention to provide a microcomputer case, which can be easily disassembled and reassembled to enable convenient expansion of internal and external hardware thereof at reduced cost.

To achieve the above and other objects, the microcomputer case according to the present invention includes a base and a top cover detachably assembled to a top of the base. The base includes a bottom wall and two side walls perpendicularly upward extended from two lateral edges of the bottom wall. Each of the two upright side walls is formed along an outer corner of a free edge with an insertion channel. The top cover is provided along two lower lateral edges with two downward extended insertion ribs corresponding to the insertion channel on the base. The insertion ribs of the top cover are slidably fitted in the insertion channels of the base to thereby detachably connect the top cover to the base.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is an exploded perspective view of a microcomputer case according to a preferred embodiment of the present invention;

FIG. 2 is an assembled perspective view of FIG. 1;

FIG. 3 is a cross-sectional view taken along line A-A of FIG. 2;

FIG. 4 is an enlarged view of the circled area of FIG. 3;

FIG. 5 is an exploded perspective view showing another height-increased top cover is assembled to the original base of the microcomputer case of the present invention to adapt to the expanded hard disk;

FIG. 6 is an assembled sectional view of FIG. 5; and

FIG. 7 is another assembled sectional view of the present invention showing a further top cover is connected to a top of the case of FIG. 6 to enclose an externally expanded device therein.

### DETAILED DESCRIPTION OF THE PREFERRED EMBODIMENTS

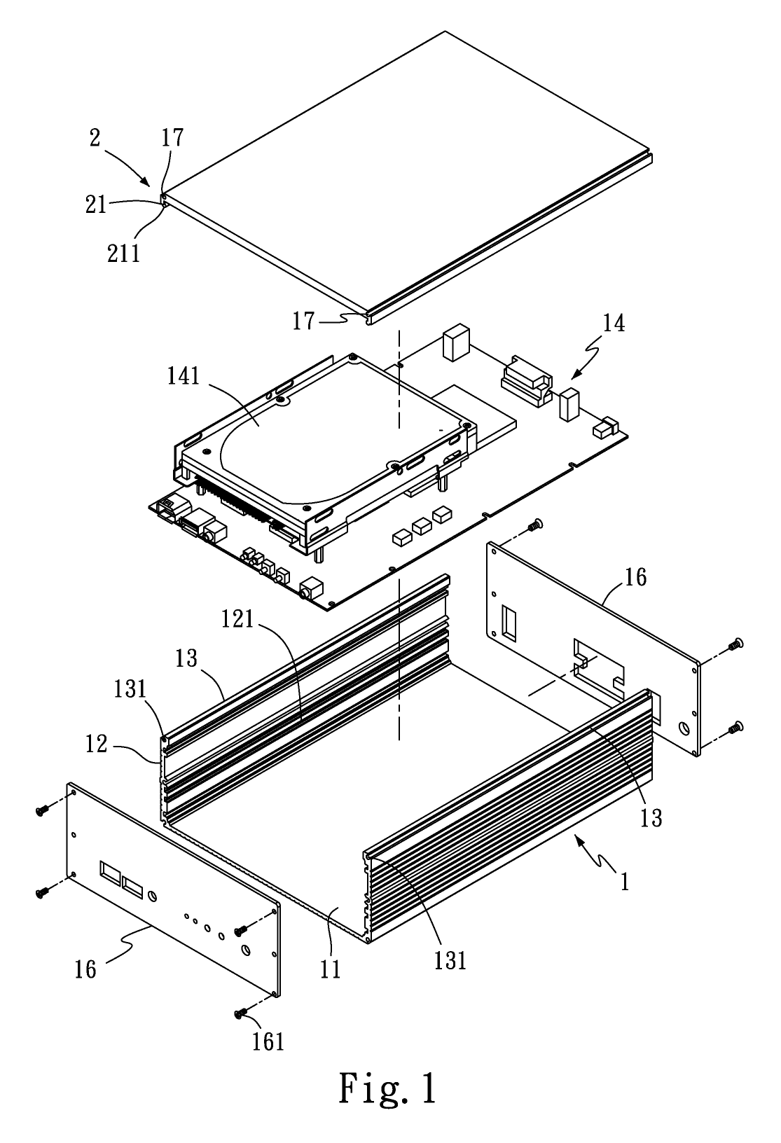

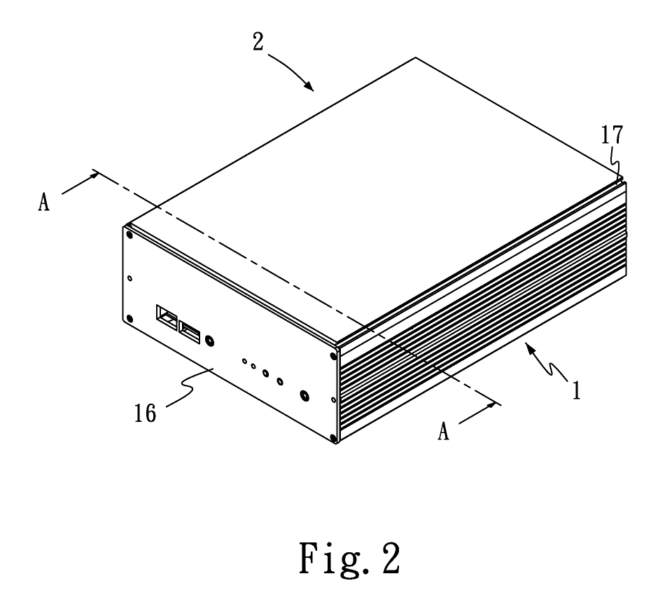

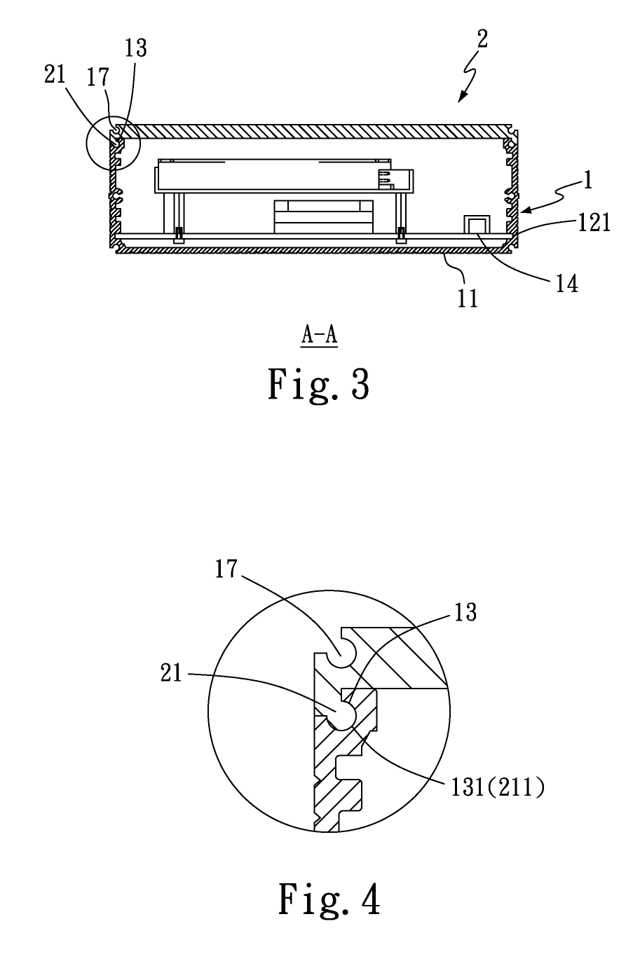

Please refer to FIGS. 1 and 2 that are exploded and assembled perspective views, respectively, of a microcomputer case according to a preferred embodiment of the present invention, and to FIG. 3 that is a cross-sectional view taken along line A-A of FIG. 2. As shown, the microcomputer case of the present invention includes a base 1 and a top cover 2 detachably assembled to a top of the base 1.

The base 1 includes a bottom wall 11 and two side walls 12 perpendicularly upward extended from two lateral edges of the bottom wall 11. Each of the upright side walls 12 has an upper free edge, along an outer corner of which an insertion channel 13 is formed. The insertion channel 13 has a bottom formed into a concave-sectioned recess 131. A plurality of slide channels 121 is symmetrically formed on two opposite surfaces of the two side walls 12. A motherboard 14 can be installed in the base 1 with two lateral sides of the motherboard 14 slidably received in two corresponding slide channels 121. Two end panels 16 are separately connected to a front and a rear open end of the base 1.

The top cover 2 has two side walls downward extended from two lower lateral edges thereof to form an insertion rib 21 each. As can be seen from FIG. 4, which is an enlarged view of the circled area of FIG. 3, lower edges of the insertion ribs 21 are formed into around-sectioned projection 211 each for correspondingly engaging with the concave-sectioned recesses 131 of the insertion channels 13, enabling the top cover 2 to be slidably and detachably assembled to the top of the base 1. In addition, two insertion channels 17 having a shape corresponding to the insertion channels 13 are formed along two upper outer edges of the top cover 2.

To assemble the microcomputer case of the present invention, a motherboard 14 is installed in the base 1 with two lateral sides slidably connected to two corresponding slide channels 121 at a predetermined height on the two upright side walls 12. Thereafter, the two insertion ribs 21 of the top cover 2 are slidably connected to the insertion channels 13 of the base 1 with the round-sectioned projections 211 engaged with the concave-sectioned recesses 131. Finally, the two end panels 16 are locked to the front and rear open ends of the base 1 by means of fastening elements 161, so as to fixedly hold the top cover 2 to the base 1. When it is desired to disassemble the top cover 2 from the base 1, simply loosen the fastening elements 161 to detach one of the two end panels 16 from the front or the rear open end of the base 1. At this point, the top cover 2 may be easily slid along the insertion channels 13 to move out of the base 1, allowing a user to proceed with necessary maintenance, repair, or replacement of the motherboard 14.

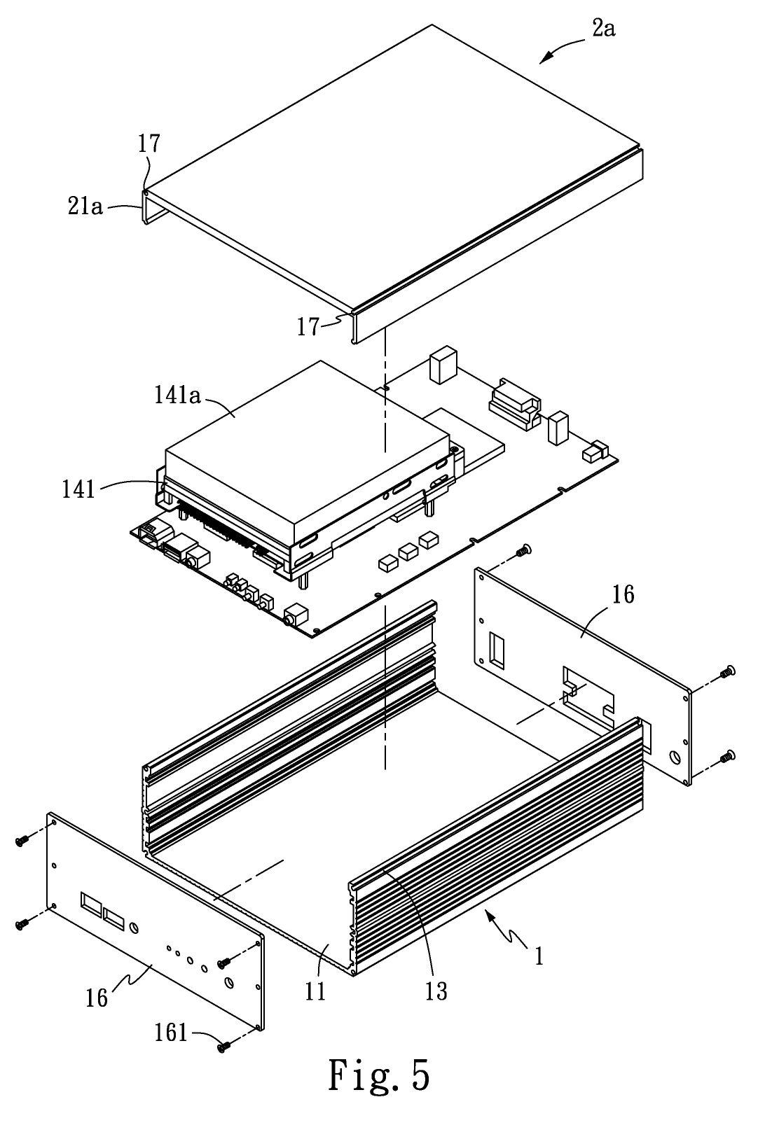

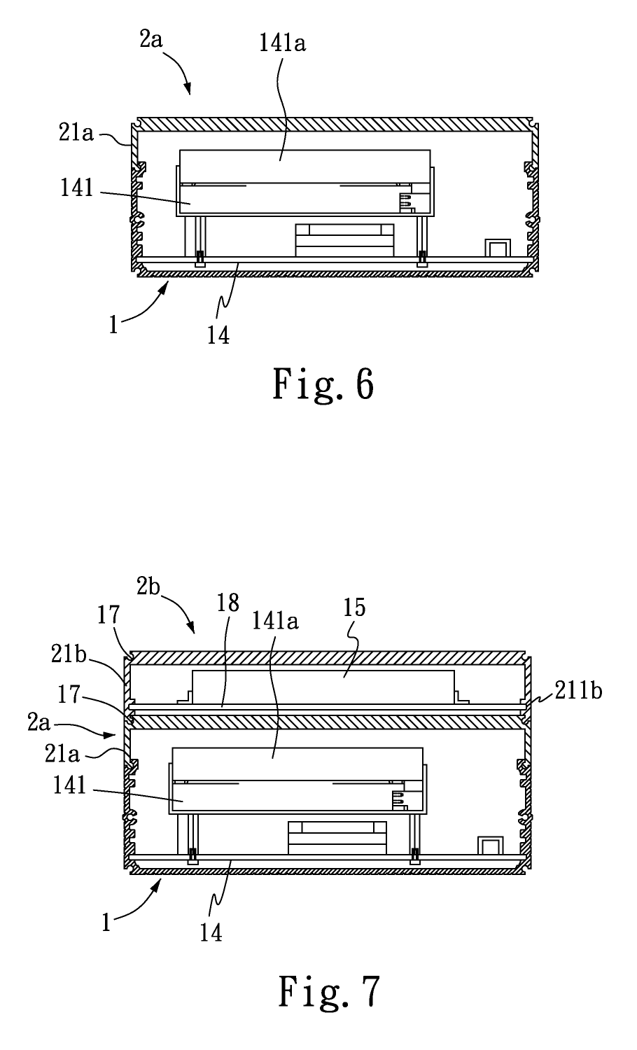

Please refer to FIGS. 5 and 6 that are exploded perspective view and assembled sectional view, respectively, showing the expansion of the microcomputer case of the present invention. When it is desired to expand hardware in the microcomputer case, one of the end panels 16 is disassembled from the base 1 in the above-described manner to slide the top cover 2 off the base 1. At this point, for example, a second hard disc 141a can be stacked on a first hard disc 141 on the motherboard 14. Or, the expansion of other hardware can be carried out at a different position on the motherboard 14. After the expansion, the hardware in the base 1 might have an overall height larger than that of the side walls 12. In this case, another top cover 2a having two higher insertion ribs 21a is used to replace the old top cover 2 and engage with the insertion channels 13 on the base 1 to increase the overall height of the microcomputer case. Accordingly, the new top cover 2a can be assembled to the base 1 in the same manner as mentioned above to form a higher case for accommodating the expanded hardware. With the above arrangements, the microcomputer case can be easily assembled and disassembled for necessary expansion of internal hardware. Meanwhile, by using top covers of different heights, different internal volumes may be created for the microcomputer case to accommodate the expanded hardware. Therefore, it is not necessary to produce a lot of complete microcomputer cases of different sizes to meet the hardware expansion, and microcomputer users could achieve the hardware expansion at reduced cost.

FIG. 7 is a sectional view showing a further application of the present invention. As shown, when it is desired to expand the microcomputer by, for example, externally connecting a CD-ROM drive 15 to a top of the microcomputer case of FIG. 6, a second top cover 2b with internally provided slide channels 211b and externally provided insertion channels 17 is additionally assembled to a top of the first top cover 2a. The CD-ROM drive 15 is mounted on an interposer 18 electrically connected to the motherboard 14. Two lateral sides of the interposer 18 are slidably fitted in the slide channels 211b, and two insertion ribs 21b of the second top cover 2b are slidably fitted in the insertion channels 17 of the first top cover 2a. After the second top cover 2b and the CD-ROM drive 15 have been assembled to the first top cover 2a, two end panels with an increased height corresponding to the total height of the base 1 and the top covers 2a, 2b are respectively locked to the front and rear open ends of the base 1 by means of fastening elements to integrate the base 1 and the two top covers 2a, 2b into a complete microcomputer case. Accordingly, the microcomputer case of the present invention may be expanded according to actual need in expansion of internal and external hardware simply by stacking additional top covers on the base.

With the above arrangements, the microcomputer case of the present invention may effectively overcome the problems in the conventional microcomputer case because it can be easily assembled and disassembled to allow convenient expansion of internal and external hardware at reduced cost.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A microcomputer case, comprising:
a base including a bottom wall and two side walls perpendicularly upward extended from two lateral edges of the bottom wall, each of the upright side walls having a free edge and an insertion channel formed along an outer corner of the free edge; and
a first top cover detachably assembled to a top of the base, the first top cover having two side walls downward extended from two lower lateral edges thereof to form two insertion ribs for slidably fitting in the insertion channels on the base.

2. The microcomputer case as claimed in claim 1, wherein a plurality of slide channels is symmetrically formed on two opposite surfaces of the two upright side walls of the base, whereby a motherboard can be installed in the base with two lateral sides of the motherboard slidably received in two corresponding ones of the slide channels; and wherein two end panels are connected to front and rear open ends of the base.

3. The microcomputer case as claimed in claim 1, wherein each of the two insertion channels on the side walls of the base has a bottom formed into a concave-sectioned recess.

4. The microcomputer case as claimed in claim 1, wherein two insertion channels are formed along two upper lateral edges of the first top cover.

5. The microcomputer case as claimed in claim 1, wherein the insertion ribs of the first top cover are downward extended by a length that is variable according to actual need.

6. The microcomputer case as claimed in claim 1, wherein the insertion ribs each have a lower edge formed into a round-sectioned projection corresponding to the concave-sectioned recesses at the bottoms of the insertion channels on the base.

7. The microcomputer case as claimed in claim 4, further comprising at least one second top cover detachably assembled to a top of the first top cover; the second top cover also having two side walls downward extended from two lower lateral edges thereof to form two insertion ribs for correspondingly slidably fitting in the two insertion channels on the first top cover.

8. The microcomputer case as claimed in claim 7, wherein two insertion channels are formed along two upper lateral edges of the second top cover.
